(19) United States
(12) Patent Application Publication
(10) Pub. No.: US 2008/0003698 A1
(43) Pub. Date: Jan. 3, 2008

(54) Film having soft magnetic properties

(76) Inventors: Chang-Min Park, Portland, OR (US); Arnel M. Fajardo, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/478,173

(22) Filed: Jun. 28, 2006

(51) Int. Cl. H01L 21/00

(52) U.S. Cl. 438/3

(57) ABSTRACT

A material capable of being applied as a film or coating on a substrate and of supplying suitable magnetic and electrical properties for magnetic applications includes cobalt, boron, and at least one of tungsten and phosphorus. The material has a resistivity between approximately 20 and 1000 μOhm-cm, a saturation magnetic flux density of between approximately 0.1 and 1.8 Tesla, a coercivity less than approximately 5 Oersted, and a relative permeability of between approximately 100 and 2000.

### FIELD OF THE INVENTION

The disclosed embodiments of the invention relate generally to magnetic applications, and relate more particularly to materials having soft magnetic properties.

### BACKGROUND OF THE INVENTION

Magnetic recording media, magnetic inductor/transformer circuitry, read/write magnetic recording heads, sensor applications, and other magnetic applications all require materials with suitable magnetic and electrical properties. Such properties are frequently imparted to a material by applying to the material a film or other coating having the appropriate characteristics. Sputtered films and nickel alloys are examples of such coatings. Unfortunately, existing coatings suffer from a variety of drawbacks making them less than desirable. Sputtering and other forms of physical vapor deposition, for example, are typically not compatible with high volume manufacturing, especially for films thicker than approximately one micrometer, due to slow deposition rates and the need for frequent target replacement. Nickel alloy raises safety and environmental concerns because Ni++ is carcinogenic. Permalloy, a nickel-iron compound frequently used as a magnetic material, suffers from eddy current loss during high frequency operation due to its low electrical resistivity. Accordingly, there exists a need for a material exhibiting both soft magnetic properties and high electrical resistivity that is compatible with a high volume manufacturing environment and that does not suffer from safety and other environmental concerns.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a material according to an embodiment of the invention that has been applied as a coating or film to an underlying substrate;

FIG. 2 is a flowchart illustrating a method according to an embodiment of the invention resulting in a structure that may be used in magnetic and other applications;

FIG. 3 is a flowchart illustrating a method of formning a cobalt film on a substrate according to an embodiment of the invention; and

FIG. 4 is a schematic representation of a system in which a material according to an embodiment of the invention may be used.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or-apparatus that comprises a list of elements is not necessarily limited to those elements, but may include other elements not expressly listed or inherent to such process, method, article, or apparatus.

The terms “left,” “right,” “front,” 37 back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

In one embodiment of the invention, a material capable of being applied as a film or coating, and capable of supplying suitable magnetic and electrical properties for magnetic applications, comprises cobalt, boron, and at least one of tungsten and phosphorus. The material has an electrical resistivity between approximately 20 and 1000 μOhm-cm, a saturation magnetic flux density of between approximately 0.1 and 1.8 Tesla, a coercivity less than approximately 5 Oersted, and a relative permeability of between approximately 100 and 2000.

With an electrical resistivity and a coercivity in the ranges given above, the material provides good material properties for multiple magnetic applications. The relatively high electrical resistivity may provide the advantage of reducing eddy current losses during high frequency operation compared to conventional magnetic materials, and the relatively low coercivity allows a more immediate response to a change in magnetism, an important quality for materials used in magnetic applications.

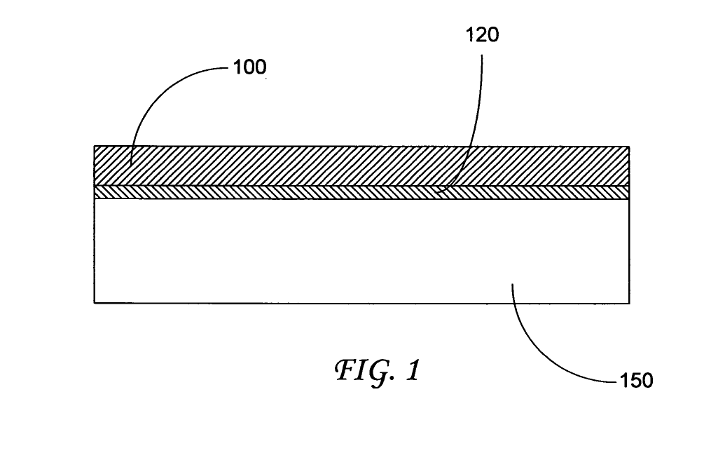

Referring now to the drawings, FIG. 1 is a cross-sectional view of a material 100 according to an embodiment of the invention that has been applied as a coating or film to a substrate 150. A seed layer 120 lies between substrate 150 and material 100. As an example, seed layer 120 can comprise copper, cobalt, nickel, platinum, palladium, ruthenium, iron, and alloys thereof.

Material 100 comprises cobalt (Co), boron (B), and at least one of tungsten (W) and phosphorus (P). Thus, material 100 may be, among other possibilities, a CoWBP film containing each of cobalt, boron, tungsten, and phosphorus, a CoBP film containing cobalt, boron, and phosphorus but not tungsten, and a CoWB film containing cobalt, boron, and tungsten but not phosphorus.

Material 100 has an electrical resistivity, subsequently referred to herein simply as the “resistivity,” between approximately 20 and approximately 1000 μOhm-cm. In one embodiment the resistivity is between approximately 50 and approximately 500 μOhm-cm, with higher resistivity values being preferred.

In certain embodiments the resistivity may be changed by making a change to a plating bath used during the deposition of material 100. Discussed below is a particular plating bath that may contain cobalt, tungstate, and a phosphorus-containing compound, each in various concentration ranges. Referring to that particular plating bath, an increase in the concentration of cobalt will tend to reduce the resistivity, while an increase in the concentration of the phosphorus-containing compound or (especially) the tungstate will tend to increase the resistivity.

Material 100 has a saturation magnetic flux density of between approximately 0.1 and approximately 1.8 Tesla. In one embodiment the saturation magnetic flux density is between approximately 0.5 and approximately 1.6 Tesla, with higher values being preferred. Referring again to the particular plating bath introduced above (and discussed in more detail below), an increase in the concentration of cobalt will tend to increase the saturation magnetic flux density up to a value of approximately 1.8 Tesla.

Material 100 further has a coercivity less than approximately 5.0 Oersted. In one embodiment the coercivity is between approximately 0.001 Oersted and approximately 2.0 Oersted, with lower values being preferred.

Still further, material 100 has a relative permeability of between approximately 100 and approximately 2000. In one embodiment the relative permeability is between approximately 700 and approximately 1000, with higher values being preferred.

It was implied above that material 100 may find utility in various magnetic applications such as magnetic recording heads and recording media, magnetic inductor/transformer circuitry, sensor applications, and the like. Additionally, material 100 can form a part of an on-chip inductor or a part of an integrated silicon voltage regulator (ISVR). Referring still to FIG. 1, material 100, as mentioned, can be thought of as being a film or coating applied to substrate 150. So applied, material 100 can form a film in a very wide range of thicknesses, such that, for example, in one embodiment material 100 may have a thickness as small as approximately 10 nanometers while in another embodiment material 100 may have a thickness as large as approximately one millimeter. As an example, in the on-chip inductor application mentioned above, material 100 may have a thickness of between approximately 0.1 micrometers and approximately 10 micrometers.

The thickness of a particular film of material 100 may have an effect on one or more of the resistivity, the saturation magnetic flux density, the coercivity, and the relative permeability. As an example, a film thickness of approximately 0.4 micrometers gives material 100 a resistivity of approximately 140 μOhm-cm, a saturation magnetic flux density of approximately 1.5 Tesla, a coercivity of approximately 0.1 Oersted, and a relative permeability of between approximately 700 and approximately 800.

It is possible to apply material 100 to substrate 150 using a dry process such as sputtering or another dry vapor deposition process, although, as mentioned above, such dry processes may lead to inefficiencies during high volume manufacturing. Wet processes may also be used in order to apply material 100 to substrate 150. For example, electrochemical deposition techniques such as electroplating, electrophoretic deposition, electroless deposition, and the like may be used in at least one embodiment and may be better suited to high volume manufacturing than are dry processes.

In an embodiment where electroless deposition is used, substrate 150 may be placed in a plating solution or plating bath as part of the deposition process. A water-based plating bath according to one embodiment of the invention comprises a primary metal in a concentration of between approximately 0.01 and approximately 0.05 moles per liter, a complexing agent in a concentration of between approximately 0.1 and approximately 0.5 moles per liter, a secondary metal in a concentration of between approximately 0.001 and approximately 0.05 moles per liter, a pH buffer in a concentration of between approximately 0.5 and approximately 1.0 moles per liter, a first reducing agent in a concentration of between approximately 0.02 and approximately 0.1 moles per liter, and a second reducing agent in a concentration of between approximately 0.02 and approximately 0.1 moles per liter.

In a particular embodiment, a pH level of the plating bath is between approximately 7.5 and approximately 9.7. In the same or another embodiment, a temperature of the plating bath is between approximately 60 degrees and approximately 90 degrees Celsius. In a particular embodiment the pH may be limited to a range between approximately 8.3 and approximately 9.7 and the temperature may be limited to a range between approximately 60 and approximately 80 degrees Celsius. Plating baths exceeding the upper limits of the stated pH and temperature ranges may become unstable. Plating baths with pH values or temperatures below the lower limits of the stated pH and temperature ranges may result in acceptable films, but the deposition process will likely proceed more slowly than when the pH value and temperature are within the stated ranges.

In one embodiment, the primary metal comprises cobalt in its (+2) oxidation state, the complexing agent comprises citrate, the secondary metal comprises tungstate (WO₄²⁻), the pH buffer comprises borate (BO₃³⁻), the first reducing agent comprises hypophosphite (H₂PO₂⁻), and the second reducing agent comprises dimethylamineborane.

It will be appreciated by one of ordinary skill in the art that the plating bath described above may be modified in certain respects yet still produce the CoWBP film, the CoBP film, the CoWB film, or the like that have been described herein. As an example, the tungstate or other secondary metal may be omitted from the plating bath. As another example, the hypophosphite or other reducing agent may be omitted from the plating bath. It will also be appreciated that if tungstate is omitted the resulting film (e.g., CoBP) may be less thermally stable than a film resulting from a plating bath in which tungstate is present. It will be further appreciated that if the hypophosphite is omitted the resulting film (e.g., CoWB) exhibits a less efficient crystallization with cobalt.

As an example, the hypophosphite can comprise ammonium hypophosphite, sodium hypophosphite, potassium hypophosphite, or the like. It will be understood by one of ordinary skill in the art that the use of ammonium hypophosphite does not give rise to the sodium contamination concerns that may arise from the use of at least sodium hypophosphite. Regardless of its particular formulation, the hypophosphite serves as a source of electrons so that metal can be formed from the metal ion present in the plating bath. (In the embodiment presented above, the hypophosphite enables cobalt to be formed from the cobalt ion.) The hypophosphite is also a source of phosphorus in material 100.

The citrate or other complexing agent complexes around the cobalt or other ion and keeps the ion in solution by preventing it from precipitating out of the plating bath. The tungstate is a source of tungsten. The borate or other pH buffer minimizes variation in pH for the plating bath. The dimethylamineborane or other secondary reducing agent also acts as a source of electrons, useful for the purpose described above, and furthermore is a source of boron in material 100.

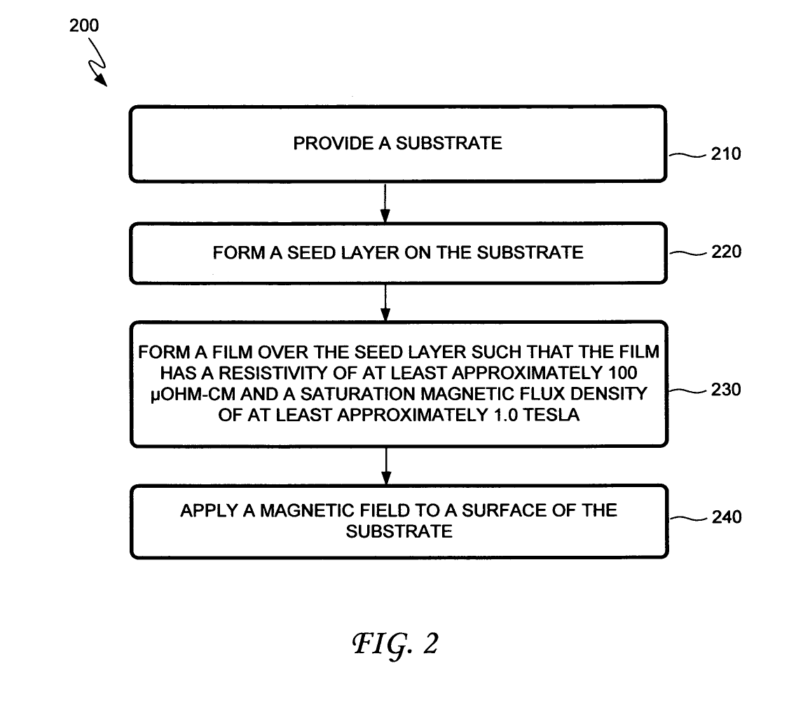

FIG. 2 is a flowchart illustrating a method 200 according to an embodiment of the invention resulting in a structure that may be used in magnetic and other applications. In at least one embodiment the structure comprises a film or other coating applied to a substrate. As an example, the film may comprise cobalt, permalloy, or another substance exhibiting soft magnetic properties.

A step 210 of method 200 is to provide a substrate. As an example, the substrate can be similar to substrate 150 shown in FIG. 1.

A step 220 of method 200 is to form a seed layer on the substrate. As an example, the seed layer can be similar to seed layer 120 shown in FIG. 1. The seed layer will typically be relatively thin—perhaps on the order of 5 to 10 nanometers depending on the nature of the film.

In one embodiment step 220 comprises depositing a material comprising a substance selected from the group consisting of copper, cobalt, nickel, platinum, palladium, ruthenium, iron, and alloys thereof. Both dry processes and wet processes are possibilities for the seed layer deposition. As an example, depositing the material to form the seed layer can comprise depositing the material using a vapor deposition method such as physical vapor deposition (PVD) or the like.

A step 230 of method 200 is to form a film over the seed layer such that the film has a resistivity of at least approximately 100 μOhm-cm and a saturation magnetic flux density of at least approximately 1.0 Tesla. In a particular embodiment step 230 further comprises forming a film having a coercivity no greater than approximately 0.001 Oersted and a relative permeability of at least approximately 700. As an example, the film can be similar to material 100 shown in FIG. 1.

In one embodiment step 230 comprises electrolessly depositing the film. In other embodiments step 230 can comprise depositing the film using other electrochemical or wet chemistry techniques, or using sputtering or other physical vapor deposition techniques. As has been discussed above, step 230 can comprise forming a CoWBP film, a CoWB film, a CoBP film, or the like.

A step 240 of method 200 is to apply a magnetic field to a surface of the substrate. In one embodiment step 240 may be performed simultaneously with step 230. In another embodiment step 240 can be performed during a heating step that follows step 230. In yet another embodiment step 240 may be merged with step 230 such that step 230 incorporates both forming the film over the seed layer and applying the magnetic field to the surface of the substrate.

As an example, step 240 can comprise applying the magnetic field parallel to or substantially parallel to the surface of the substrate and at a strength of greater than approximately 100 Oersted. As a particular example, step 240 can comprise applying the magnetic field at a strength between approximately 500 and approximately 1000 Oersted. The magnetic field may be applied using permanent or electromagnets. Application of the magnetic field parallel or substantially parallel to the substrate surface may be necessary in order to induce uniaxial anisotropy, which is needed in order to obtain high permeability and linear operation of magnetic inductors and other magnetic circuits.

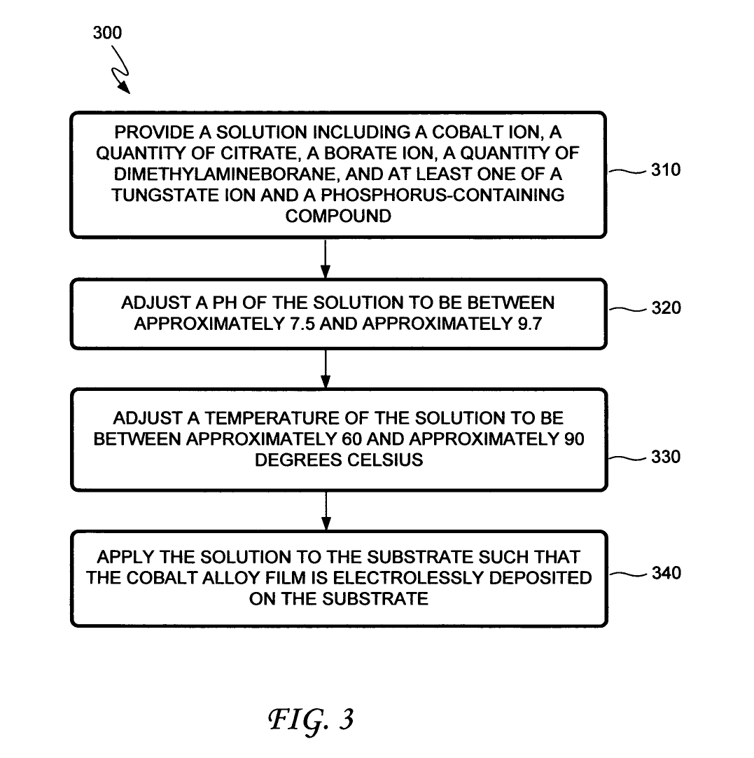

FIG. 3 is a flowchart illustrating a method 300 of forming a cobalt film on a substrate according to an embodiment of the invention. A step 310 of method 300 is to provide a solution including a cobalt ion, a quantity of citrate, a borate ion, a quantity of dimethylamineborane, and at least one of a tungstate ion and a phosphorus-containing compound. As an example, the phosphorus-containing compound can comprise a hypophosphite, such as ammonium hypophosphite, sodium hypophosphite, potassium hypophosphite, or the like.

A step 320 of method 300 is to adjust a pH of the solution to be between approximately 7.5 and approximately 9.7. In one embodiment, step 320 comprises adding an alkaline agent to the solution in a concentration of between approximately 5 percent and approximately 15 percent by weight prior to applying the solution to the substrate. As an example, the alkaline agent can be tetramethylammonium hydroxide (TMAH) [(CH₃)₄NOH], potassium hydroxide (KOH), or the like.

A step 330 of method 300 is to adjust a temperature of the solution to be between approximately 60 and approximately 90 degrees Celsius.

A step 340 of method 300 is to apply the solution to the substrate such that the cobalt alloy film is electrolessly deposited on the substrate. Step 340 or another step of method 300 may further comprise applying a magnetic field to a surface of the substrate as described above in connection with step 240 of method 200.

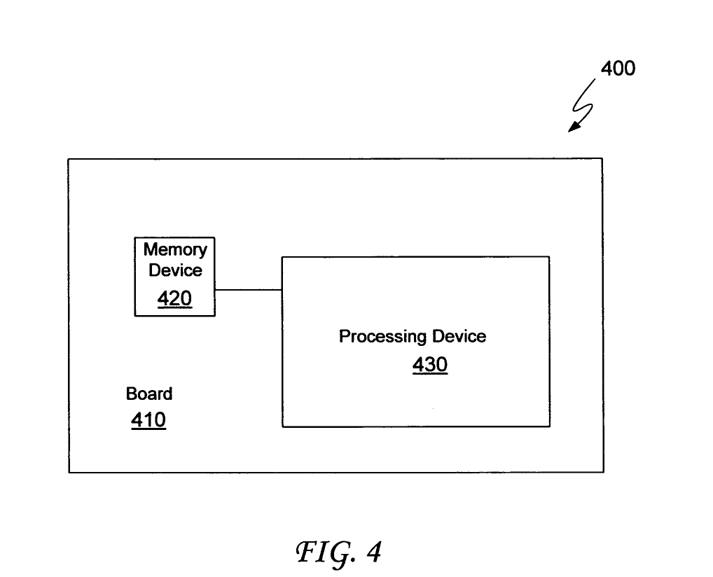

FIG. 4 is a schematic representation of a system 400 in which a material according to an embodiment of the invention may be used. As illustrated in FIG. 4, system 400 comprises a board 410, a memory device 420 disposed on board 410, and a processing device 430 disposed on board 410 and coupled to memory device 420. Processing device 430 comprises a substrate (not shown in FIG. 4) coated with a film (also not shown in FIG. 4) comprising cobalt, boron, and at least one of tungsten and phosphorus (which in one embodiment can be in the form of ammonium hypophosphite, sodium hypophosphite, potassium hypophosphite, or the like).

As an example, the substrate and the film can be similar to, respectively, substrate 150 and material 100, both of which were shown in FIG. 1, such that in at least one embodiment the film has a resistivity of at least approximately 100 μOhm-cm, a saturation magnetic flux density of at least approximately 1.0 Tesla, a coercivity no greater than approximately 0.001 Oersted, and a relative permeability of at least approximately 700.

In a particular embodiment the film has a thickness of approximately 0.4 micrometers and the resistivity is approximately 140 μOhm-cm, the saturation magnetic flux density is approximately 1.5 Tesla, the coercivity is approximately 0.1 Oersted, and the relative permeability is between approximately 700 and approximately 800.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the material, the plating bath, and the associated methods and system discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A material comprising:
cobalt, boron, and at least one of tungsten and phosphorus,
wherein the material has:
a resistivity between approximately 20 and approximately 1000 μOhm-cm;
a saturation magnetic flux density of between approximately 0.1 and approximately 1.8 Tesla;
a coercivity less than approximately 5 Oersted; and
a relative permeability of between approximately 100 and approximately 2000.

2. The material of claim 1 wherein:
the material comprises a film coating a substrate and having a thickness of approximately 0.4 micrometers.

3. The material of claim 1 wherein:
the material comprises both tungsten and phosphorus.

4. The material of claim 1 wherein:
the resistivity is between approximately 50 and approximately 500 μOhm-cm.

5. The material of claim 1 wherein:
the saturation magnetic flux density is between approximately 0.5 and approximately 1.6 Tesla.

6. The material of claim 1 wherein
the coercivity is between approximately 0.001 and approximately 2.0 Oersted.

7. The material of claim 1 wherein:
the relative permeability is between approximately 700 and approximately 1000.

8. A plating bath comprising:
a primary metal in a concentration of between approximately 0.01 and approximately 0.05 moles per liter;
a complexing agent in a concentration of between approximately 0.1 and approximately 0.5 moles per liter;
a secondary metal in a concentration of between approximately 0.001 and approximately 0.05 moles per liter;
a pH buffer in a concentration of between approximately 0.5 and approximately 1.0 moles per liter;
a first reducing agent in a concentration of between approximately 0.02 and approximately 0.1 moles per liter; and
a second reducing agent in a concentration of between approximately 0.02 and approximately 0.1 moles per liter.

9. The plating bath of claim 8 wherein:
a pH level of the plating bath is between approximately 7.5 and approximately 9.7.

10. The plating bath of claim 8 wherein:
a temperature of the plating bath is between approximately 60 degrees and approximately 90 degrees Celsius.

11. The plating bath of claim 8 wherein:
the primary metal comprises cobalt in its (+2) oxidation state.

12. The plating bath of claim 8 wherein:
the complexing agent comprises citrate.

13. The plating bath of claim 8 wherein:
the secondary metal comprises tungstate.

14. The plating bath of claim 8 wherein:
the pH buffer comprises borate.

15. The plating bath of claim 8 wherein:
the first reducing agent comprises hypophosphite.

16. The plating bath of claim 15 wherein:
the hypophosphite comprises ammonium hypophosphite.

17. The plating bath of claim 8 wherein:
the second reducing agent comprises dimethylamineborane.

18. A method comprising:
providing a substrate;
forming a seed layer on the substrate; and
forming a film over the seed layer such that the film has a resistivity of at least approximately 100 μOhm-cm and a saturation magnetic flux density of at least approximately 1.0 Tesla.

19. The method of claim 18 wherein:
forming the film comprises forming a CoWBP film.

20. The method of claim 19 wherein:
the CoWBP film has a coercivity no greater than approximately 0.001 Oersted and a relative permeability of at least approximately 700.

21. The method of claim 18 wherein:
forming the seed layer comprises depositing a material comprising a substance selected from the group consisting of copper, cobalt, nickel, platinum, palladium, ruthenium, iron, and alloys thereof.

22. The method of claim 21 wherein:
depositing the material to form the seed layer comprises depositing the material using a vapor deposition method.

23. The method of claim 18 wherein:
forming the film comprises electrolessly depositing the film.

24. The method of claim 18 further comprising:
applying a magnetic field to a surface of the substrate.

25. The method of claim 24 wherein:
applying the magnetic field comprises applying the magnetic field parallel to or substantially parallel to the surface of the substrate and at a strength of greater than approximately 100 Oersted.

26. The method of claim 25 wherein:
applying the magnetic field comprises applying the magnetic field at a strength between approximately 500 and approximately 1000 Oersted.

27. A method of forming a cobalt alloy film on a substrate, the method comprising:
providing a solution including:
a cobalt ion;
a quantity of citrate;
a borate ion;
a quantity of dimethylamineborane; and
at least one of a tungstate ion and a phosphorus-containing compound; and
applying the solution to the substrate such that the cobalt alloy film is electrolessly deposited on the substrate.

28. The method of claim 27 further comprising:
adjusting a pH of the solution to be between approximately 7.5 and approximately 9.7; and
adjusting a temperature of the solution to be between approximately 60 and approximately 90 degrees Celsius.

29. The method of claim 28 wherein:
adjusting the pH of the solution comprises adding an alkaline agent in a concentration of between approximately 5 percent and approximately 15 percent by weight to the solution prior to applying the solution to the substrate.

30. A system comprising:
a board;
a memory device disposed on the board; and
a processing device disposed on the board and coupled to the memory device, where the processing device comprises a substrate coated with a film comprising cobalt, boron, and at least one of tungsten and phosphorus,
wherein the film has:
a resistivity of at least approximately 100 μOhm-cm;
a saturation magnetic flux density of at least approximately 1.0 Tesla;
a coercivity less than approximately 5 Oersted; and
a relative permeability of at least approximately 700.

31. The system of claim 30 wherein:
the film has a thickness of approximately 0.4 micrometers;
the resistivity is approximately 140 μOhm-cm;
the saturation magnetic flux density is approximately 1.5 Tesla;
the coercivity is approximately 0.1 Oersted; and
the relative permeability is between approximately 700 and approximately 800.
